(19) United States
(12) Patent Application Publication
(10) Pub. No.: US 2023/0235501 A1
(43) Pub. Date: Jul. 27, 2023

(54) A METHOD FOR FABRICATING CONDUCTIVE YARNS AND FABRICS AT ROOM TEMPERATURE

(71) Applicant: National Research Council of Canada, Ottawa (CA)

(72) Inventors: Zhiyi ZHANG, Ottawa (CA); Ye TAO, Ottawa (CA); Gaozhi XIAO, Ottawa (CA); Ta-Ya CHU, Ottawa (CA)

(21) Appl. No.: 18/012,132

(22) PCT Filed: Jun. 22, 2021
(86) PCT No.: PCT/CA2021/050850

§ 371 Date: Dec. 21, 2022

Related U.S. Application Data
(60) Provisional application No. 63/042,136, filed on Jun. 22, 2020.

(51) Int. Cl. D06M 11/83; H01B 1/22; H05K 1/03; H05K 1/09

(52) U.S. Cl. CPC D06M 11/83; H01B 1/22; H05K 1/038; H05K 1/09; H05K 2201/0281

(57) ABSTRACT

A method of fabricating a conductive yarn comprising a plurality of filaments, the method comprising the steps of: (a) applying a reducing agent solution to the treated surface; and (b) applying a metal ion solution to the treated at least one of the lurality of filaments. The method comprising a further step of treating the surface of the at least one of the plurality of filaments with a hydrophilic agent before performing steps (a) and (b).

### FIELD

Aspects of the disclosure relate to printable electronics, particularly to a process for depositing a metal on a substrate.

### BACKGROUND

Conductive yarns and fabrics are basic components in wearable electronics. Typical conductive yarns are fabricated by coating metal nanoparticles, such as silver nanoparticles, to directly form a silver film on yarn filaments through the reduction of silver ions. However, silver nanoparticles are expensive to synthesize and therefore it is relatively costly to use these nanoparticles to coat yarns, and it can be challenging to coat each individual filament with a dense layer of silver in a yarn. Conductive yarns can be also made from electroless plating process which is long and costing. As such, the high cost these conductive yarns and fabrics has limited their use in wearable electronics, and other applications.

It is an object of the present disclosure to mitigate or obviate at least one of the above-mentioned disadvantages.

### SUMMARY

In one aspect of the disclosure, there is provided a method of fabricating a conductive yarn comprising a plurality of filaments, the method comprising the steps of:
(a) applying a reducing agent solution to a surface of at least one of the plurality of filaments; and
(b) applying a metal ion solution to the at least one of the plurality of filaments.

In another aspect of the disclosure, there is provided method of fabricating a conductive yarn comprising a plurality of filaments, the method comprising the steps of:
(a) treating a surface of at least one of the plurality of filaments with a hydrophilic agent;
(b) applying a reducing agent solution to the treated surface;
(c) applying a metal ion solution to the treated at least one of the plurality of filaments.

Advantageously, there is provided a method of fabricating conductive yarns with lower resistivity, and the method is associated with less cost, and less complex processing.

### BRIEF DESCRIPTION OF THE DRAWINGS

Several exemplary embodiments of the present disclosure will now be described, by way of example only, with reference to the appended drawings in which:

FIG. 1 shows a flowchart with exemplary steps for a method of fabricating conductive yarns and fabrics, in an exemplary embodiment;

FIG. 2 shows a cross-section of a yarn filament along the filament;

FIGS. 3a and 3b show optical microscopy images of the obtained conductive yarns;

FIG. 4 shows a graph illustrating the electrical resistance of conductive yarns as a function of their length compared to T150d conductive yarns;

FIG. 5 shows the effects of winding and unwinding of conductive yarns on the performance of the conductive yarns;

FIG. 6 shows the effects of water soaking on the performance of conductive yarns;

FIG. 7 shows the effects of temperature on the performance of conductive yarns;

FIG. 8 shows a conductive line formed on a piece of fabric material; and

FIG. 9 shows a conductive pattern formed on a piece of fabric material through printing.

### DETAILED DESCRIPTION

The following detailed description refers to the accompanying drawings. Wherever possible, the same reference numbers are used in the drawings and the following description to refer to the same or similar elements. While embodiments of the disclosure may be described, modifications, adaptations, and other implementations are possible. For example, substitutions, additions, or modifications may be made to the elements illustrated in the drawings, and the methods described herein may be modified by substituting, reordering, or adding stages to the disclosed methods. Accordingly, the following detailed description does not limit the disclosure. Instead, the proper scope of the disclosure is defined by the appended claims.

Moreover, it should be appreciated that the particular implementations shown and described herein are illustrative of one aspect of the disclosure and are not intended to otherwise limit the scope of the present disclosure in any way. Indeed, for the sake of brevity, certain sub-components of the individual operating components, and other functional aspects of the systems may not be described in detail herein. Furthermore, the connecting lines shown in the various figures contained herein are intended to represent exemplary functional relationships and/or physical couplings between the various elements. It should be noted that many alternative or additional functional relationships or physical connections may be present in a practical system.

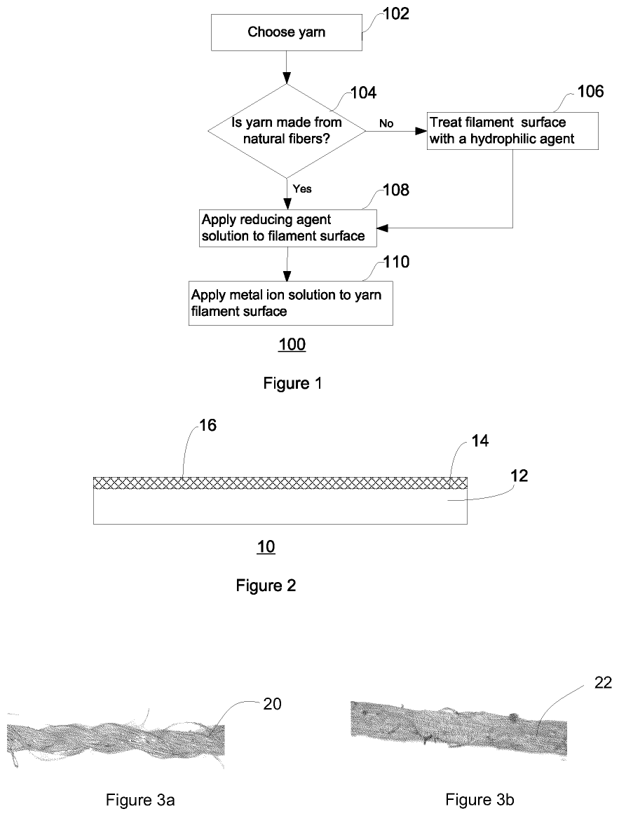

FIG. 1 shows flowchart 100 with exemplary steps for a method of fabricating conductive yarns 10, in an exemplary embodiment. Generally, as shown in FIG. 2, yarn 10 comprises a long continuous length of one or more filaments 12 having surface 14, suitable for use in the production of textiles, sewing, crocheting, knitting, weaving, or embroidery. In step 102, a type of yarn is selected. Generally, yarn 10 is made from natural fiber materials, such as, cotton, silk, wool, or synthetic materials, such as, polyester, nylon, acrylic, polypropylene and others, is generally not hydrophilic. Next, a determination is made as to whether filament surface 14 in yarns 10 is hydrophilic or not, step 104. Generally, yarn 10 is made from natural materials is hydrophilic, while yarn 10 made from synthetic materials is generally not hydrophilic.

In step 106, when the selected yarn 10 material is natural, surface 14 is sufficiently hydrophilic, step 108 below is implemented. Otherwise surface 14 of filament 12 of synthetic yarn 10 is first treated with a hydrophilic agent in step 106, which performs surface modification through a surface chemical reaction.

Next, in step 108, a reducing agent solution is applied to treated surface 14. A reducing agent, such as hydroxylamine, reduces metal ions at room temperature, and comprises a surfactant or surfactant mixture or one or more solvents with low surface energy such that the reducing agent solution can wet the filament surface. Accordingly, the reducing agent is chosen to have a low viscosity solution, as described in applicant's U.S. Patent No. 10,000,652, the contents of which are incorporated herein by reference in its entirety.

In step 110, a metal ion solution is applied to yarn filament surface 14. The metal ion solution comprises at least one of silver, copper, gold, and aluminum ions. Generally, the surface energy of both the reduction solution and silver ion solutions is substantially reduced, and a surfactant or surfactant mixture may be added into the solutions to allow them to impregnate yarns 10 and properly wet filaments 12 within yarns 10. Next, in step 110, a metal ion solution is applied to the yarn filament surface 14 again to increase the deposition of metal ions on surface 14 to form continuous films of metal 16. Since filaments 14 are twisted and in close contact in yarns 10, especially, in commercial sewing machine threads, and it may be difficult to wet the filament-to-filament contacted area, therefore a yarn swelling process in water may be used to reduce the contact between filaments 12, and separate filaments 12 from each other.

FIGS. 3a and 3b show optical microscopy images of obtained conductive yarns from sewing machine threads yarns 10, that is, polyester yarns 20 and cotton yarns 22.

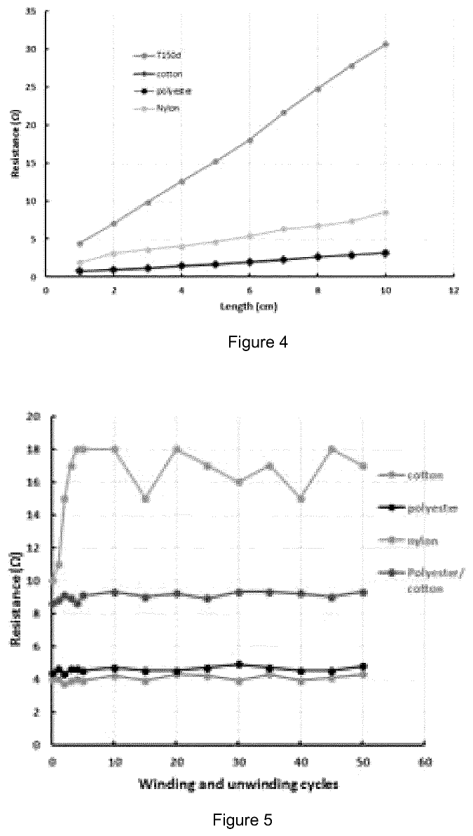

FIG. 4 shows the performance of conductive yarns 20, 22 fabricated by the process of flowchart 100 in comparison with commercially-available T150D. The electrical resistance of conductive cotton yarns 22 is less than 0.3 Ω/cm, and electrical resistance of polyester yarns 20 and is less than 0.8 Ω/cm. In comparison, the commercial yarns, have an electrical resistance of 3 Ω/cm.

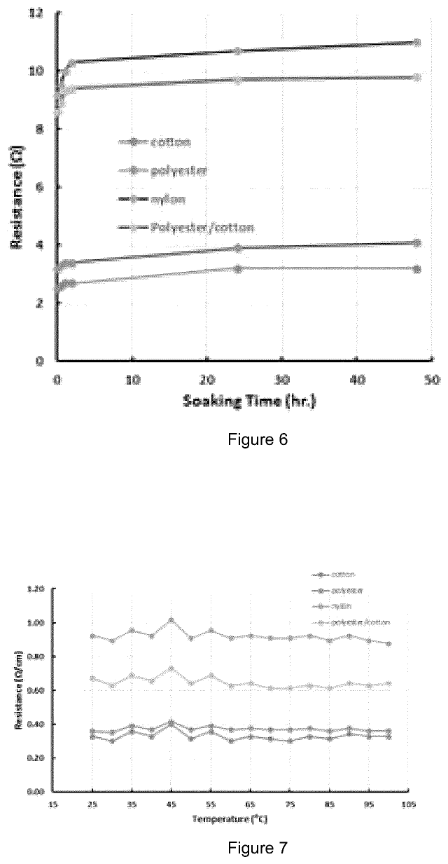

In order to evaluate the reliability, the mechanical performance of the conductive yarns 20, 22 was tested by winding and unwinding conductive yarns 20, 22 on a spool and measuring the resistance after each unwinding. In one test, the spool had a diameter of 6.7 mm. FIG. 5 shows the effects of winding and unwinding of conductive yarns 20, 22 on their performance. As can be seen in FIG. 5, the winding and unwinding cycle was shown not to affect the performance. Conductive yarns 20, 22 were also soaked in water to investigate the water attack, and FIG. 6 shows the effect of water soaking. No significant change was observed from the tested period. FIG. 7 shows the performance of conductive yarns 20, 22 at various temperatures. No change was tested up to 100° C.

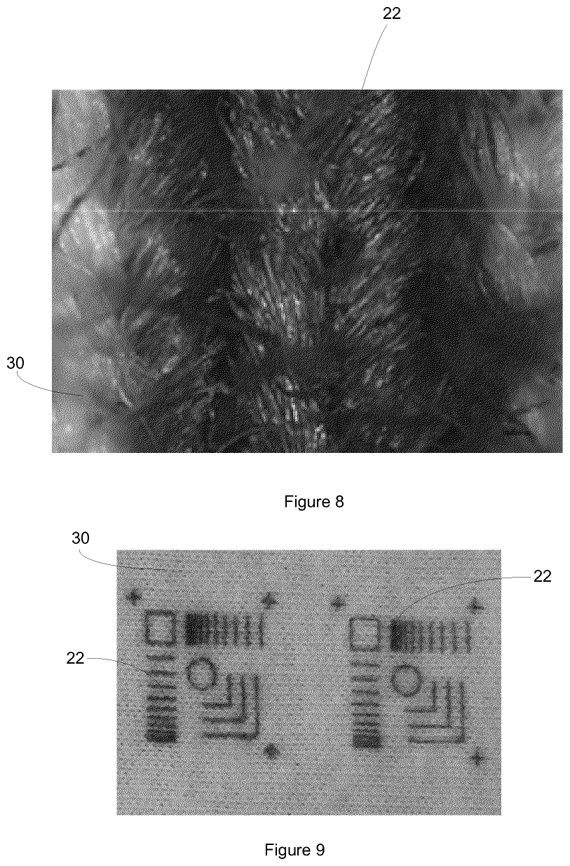

In another implementation, conductive fabrics may be fabricated using the same method described above. The fabrics may be fabricated to be conductive for the whole area or conductive in a selected area. For the whole conductive fabrics, the process for fabricating conductive yarn can be directly used. For the fabrics with conductive patterns, printing can be used to apply the reducing agent and metal ion solution to the selected area. FIG. 8 shows the area of fabric 30, such as a white T-shirt surface, with a line formed of conductive yarns 20. FIG. 9 shows a pattern made by conductive yarns 20 formed on an area of fabric 30.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Embodiments are described above with reference to block diagrams and/or operational illustrations of methods, systems. The operations/acts noted in the blocks may be skipped or occur out of the order as shown in any flow diagram. For example, two or more blocks shown in succession may be executed substantially concurrently or the blocks may sometimes be executed in the reverse order, depending upon the functionality/acts involved. While the specification includes examples, the disclosure's scope is indicated by the following claims. Furthermore, while the specification has been described in language specific to structural features and/or methodological acts, the claims are not limited to the features or acts described above. Rather, the specific features and acts described above are disclosed as example for embodiments.

1. A method of fabricating a conductive yarn comprising a plurality of filaments, the method comprising the steps of:
(a) applying a reducing agent solution to a surface of at least one of the plurality of filaments; and
(b) applying a metal ion solution to the at least one of the plurality of filaments.

2. The method of claim 1, wherein the reducing agent solution reduces metal ions at room temperature.

3. The method of claim 1, wherein the metal ion solution comprises at least one silver, copper, gold, and aluminum ions.

4. The method of claim any one of claims 1 to 3, wherein surfactants are used in each step.

5. The method of claim 1, wherein the steps (a) and b) are implemented in one sequence.

6. The method of claim 1, wherein the steps (a) and (b) are repeated multiple times with each cycle.

7. The method of claim 1, wherein the reducing agent is at least one of hydroxylamine, hydroxylamine and its reaction products with organic and/or inorganic acids, and any mixture thereof

8. The method of any one of claims 1 to 7, wherein the yarn is made from natural materials selected from a group comprising: cotton, silk, wool, and linen.

9. The method any one of claims 1 to 7, wherein the yarn is made from synthetic materials selected from a group comprising: polyester, nylon, acrylic, polypropylene and others, the method comprising a further step of treating the surface of the at least one of the plurality of filaments with a hydrophilic agent before performing steps (a) and (b).

10. The method of claim 9, wherein the hydrophilic agent performs surface chemical modification through surface chemical reaction.

11. The method of any one of claims 8 to 10, wherein the yarn is made from a combination of natural materials and synthetic materials.

12. The method any one of claims 1 to 11, wherein a conductive pattern is formed in a selected area of a fabric material.

13. A method of fabricating a conductive yarn comprising a plurality of filaments, the method comprising the steps of:
(a) treating a surface of at least one of the plurality of filaments with a hydrophilic agent;
(b) applying a reducing agent solution to the treated surface;
(c) applying a metal ion solution to the treated at least one of the plurality of filaments.

14. The method of claim 13, wherein the reducing agent solution reduces metal ions at room temperature.

15. The method of claim 14, wherein the metal ion solution comprises at least one silver, copper, gold, and aluminum ions.

16. The method of claim 14, wherein the surface energy of both the reducing agent solution and metal ion solution is substantially reduced.

17. The method of claim 16, wherein a surfactant or surfactant mixture is added into the reducing agent solution and metal ion solution.

18. The method of any one of claims 13 to 17, wherein the metal ion solution is applied to the surface of at the least one of the plurality of filaments to increase the deposition of metal ions the surface to form continuous films of metal.

19. The method of any one of claims 13 to 18, wherein the yarn is made from synthetic materials selected from a group comprising polyester, nylon, acrylic, and polypropylene.

20. The method of claim 19, wherein the electrical resistance of the conductive polyester yarns and is less than 0.8 Ω.

21. The method of any one of claims 13 to 18, wherein the yarn is made from natural materials selected from a group comprising: cotton, silk, wool, and linen.

22. The method of claim 21, wherein the electrical resistance of conductive cotton yarns is less than 0.3 Ω/cm.

23. The method of any one of claims 13 to 18, wherein the yarn is made from a combination of natural materials and synthetic materials.

24. The method any one of claims 13 to 23, wherein a conductive pattern formed of the conductive yarn is formed in a selected area of a fabric material.

25. The method any one of claims 13 to 24, wherein the plurality of filaments undergo a yarn swelling process to reduce the contact between the plurality of filaments and separate the plurality of filaments from each other.

26. The method of claim 25, wherein the yarn swelling process involves exposing the plurality of filaments to at least one of water and steam.

27. The method any one of claims 13 to 26, wherein the method is performed at room temperature.
